(19) United States
(12) Patent Application Publication
(10) Pub. No.: US 2024/0408697 A1
(43) Pub. Date: Dec. 12, 2024

(54) WAFER MANUFACTURING METHOD AND PROCESSING APPARATUS

(71) Applicant: DISCO CORPORATION, Tokyo (JP)

(72) Inventor: Kazuya HIRATA, Tokyo (JP)

(21) Appl. No.: 18/676,810

(22) Filed: May 29, 2024

(30) Foreign Application Priority Data
Jun. 9, 2023 (JP) 2023-095272

(51) Int. Cl. B23K 26/00; B23K 26/38; B23K 26/53; B23K 101/40

(52) U.S. Cl. CPC B23K 26/0093; B23K 26/38; B23K 26/53; B23K 2101/40

(57) ABSTRACT

In a flattening step included in a series of steps for manufacturing wafers from an ingot, the ingot is ground until the ingot has a thickness smaller than a thickness of the ingot as of the point in time when the series of steps is to be started, by a thickness obtained by adding up a finishing thickness of the wafer, an assumed thickness of a separation layer, and a distributed thickness obtained by dividing a surplus thickness of the ingot by a number obtained by subtracting one from a maximum number of wafers that can be manufactured from the ingot.

### BACKGROUND OF THE INVENTION

### Field of the Invention

The present invention relates to a wafer manufacturing method for manufacturing three or more wafers from an ingot and a processing apparatus therefor.

### Description of the Related Art

Semiconductor device chips are typically manufactured with use of a wafer including a single crystal of silicon (Si), silicon carbide (SiC), gallium nitride (GaN), lithium tantalate (LiTaO₃: LT), or lithium niobate (LiNbO₃: LN), for example. This wafer is, for example, manufactured by being cut out from the ingot by a wire saw.

The cutting allowance for cutting out the wafer from the ingot by a wire saw is approximately 300 μm, which is relatively large. Moreover, minute surface irregularities are formed on a surface of the wafer which has been cut out as described above, and this wafer would be curved in whole (warp would occur in the wafer). Hence, when this wafer is to be used to manufacture chips, the surface of the wafer needs to be flattened by lapping, etching, and/or polishing being applied thereto.

In this case, the final amount of material used as the wafer is approximately two-thirds of the total amount of ingot. Stated differently, approximately one-third of the total amount of ingot is discarded when the wafer is cut out from the ingot and subsequently flattened on the surface thereof. Hence, manufacturing the wafer by a wire saw in the manner described above tends to lower productivity.

In light of this situation, there has been proposed a wafer manufacturing method for manufacturing a wafer from an ingot with use of a laser beam having a wavelength transmittable through the material of the ingot (see, for example, Japanese Patent Laid-open No. 2019-12765). Specifically, in this method, first, while a laser beam is applied to an ingot in such a manner that a focal point at which the laser beam is focused is positioned inside the ingot, the focal point and the ingot are moved relative to each other.

This leads to formation of a separation layer including modified portions and cracks extending from the modified portions inside the ingot. Further, in this method, external force is applied to the ingot such that the cracks further extend. Consequently, the ingot is separated at the separation layer, and a wafer is manufactured.

Further, when the wafer is manufactured from the ingot in this way, a separation layer (an ingot-side remaining separation layer and a wafer-side remaining separation layer) remains in each of the ingot and the wafer. Hence, in the wafer manufacturing method described above, each of the ingot and the wafer is ground, so that the ingot-side remaining separation layer and the wafer-side remaining separation layer are each removed, and each of the ingot and the wafer is flattened.

### SUMMARY OF THE INVENTION

When the abovementioned wafer manufacturing method is repeated, an ingot having a thickness slightly smaller than the thickness necessary for manufacturing two wafers is sometimes left. In this case, the last wafer is manufactured by the ingot being ground over a long period of time until a finishing thickness of the wafer is obtained.

Yet, when a maximum number of wafers are to be manufactured from each ingot while a plurality of ingots are simultaneously processed, grinding each ingot over a long period of time for manufacturing the last wafer might become a bottleneck. In other words, in this case, when the last wafer is to be manufactured by grinding a specific ingot, processing of other ingots may be suspended over a long period of time.

In view of such a problem, an object of the present invention is to provide a wafer manufacturing method that is capable of reducing the length of time necessary for manufacturing the maximum number of wafers from each ingot while a plurality of ingots are processed simultaneously and a processing apparatus to be used for the wafer manufacturing method.

In accordance with an aspect of the present invention, there is provided a wafer manufacturing method for manufacturing three or more wafers from an ingot by repeating a series of steps including a separation layer forming step of forming a separation layer inside the ingot, a separating step of manufacturing each of the wafers by separating the ingot at the separation layer, after the separation layer forming step, and a flattening step of flattening each of the ingot and the wafer by removing each of an ingot-side remaining separation layer remaining in the ingot and a wafer-side remaining separation layer remaining in the wafer, after the separating step, the wafer manufacturing method including a calculating step of calculating a maximum number of the wafers manufacturable from the ingot and a surplus thickness of the ingot by referring to an initial thickness of the ingot, a finishing thickness of the wafer, and an assumed thickness of the separation layer, prior to manufacturing three or more of the wafers from the ingot. In the separation layer forming step, the separation layer is formed by moving, relative to each other, the ingot and a focal point where a laser beam having a wavelength transmittable through a material of the ingot is focused, while the laser beam is applied to the ingot such that the focal point is positioned to a predetermined depth from a face side of the ingot, and, in the flattening step, the ingot is ground until the ingot has a thickness smaller than a thickness of the ingot as of the point in time when the series of steps is to be started, by a thickness obtained by adding up the finishing thickness, the assumed thickness, and a distributed thickness obtained by dividing the surplus thickness by a number obtained by subtracting one from the maximum number, and the wafer is ground until the wafer has the finishing thickness.

Preferably, the predetermined depth is a depth corresponding to a first thickness obtained by adding up the finishing thickness and a thickness of the wafer-side remaining separation layer. Alternatively, the predetermined depth is preferably a depth corresponding to a second thickness obtained by adding up the finishing thickness, a thickness of the wafer-side remaining separation layer, and the distributed thickness. Still alternatively, the predetermined depth is preferably a depth greater than a first thickness obtained by adding up the finishing thickness and a thickness of the wafer-side remaining separation layer but smaller than a second thickness obtained by adding up the first thickness and the distributed thickness.

In accordance with another aspect of the present invention, there is provided a processing apparatus for manufacturing three or more wafers from an ingot, including a laser processing unit for forming a separation layer inside the ingot, a separating unit for manufacturing each of the wafers by separating the ingot at the separation layer, a flattening unit for flattening the ingot by removing an ingot-side remaining separation layer remaining in the ingot, and a controller that controls the laser processing unit, the separating unit, and the flattening unit such that a series of steps including forming of the separation layer, separating of the ingot, and flattening of the ingot is repeated the number of times obtained by subtracting one from a maximum number of the wafers manufacturable from the ingot, in which the controller includes a memory for storing an initial thickness of the ingot, a finishing thickness of the wafers, and an assumed thickness of the separation layer, and a processor for calculating the maximum number and a surplus thickness of the ingot by referring to the initial thickness, the finishing thickness, and the assumed thickness, and the processor controls the laser processing unit such that the separation layer is formed by moving, relative to each other, the ingot and a focal point where a laser beam having a wavelength transmittable through a material of the ingot is focused, while the laser beam is applied to the ingot in such a manner that the focal point is positioned to a predetermined depth from a face side of the ingot, and controls the flattening unit such that the ingot is ground until the ingot has a thickness smaller than a thickness of the ingot as of the point in time when the series of steps is to be started, by a thickness obtained by adding up the finishing thickness, the assumed thickness, and a distributed thickness obtained by dividing the surplus thickness by a number obtained by subtracting one from the maximum number.

In the flattening step (specifically, the flattening of the ingot) included in the series of steps for manufacturing wafers from an ingot according to the present invention, the ingot is ground until the ingot has a thickness that is smaller than the thickness of the ingot as of the point in time when the series of steps is to be started, by a thickness obtained by adding up the finishing thickness of the wafer, the assumed thickness of the separation layer, the distributed thickness obtained by dividing the surplus thickness of the ingot by a number obtained by subtracting one from the maximum number of wafers manufacturable from the ingot.

When this series of steps is repeated, an ingot having a thickness that is equal to or greater than a minimum thickness of the ingot necessary for manufacturing the last wafer (specifically, a thickness obtained by adding up the finishing thickness of the wafer and the thickness of the ingot-side remaining separation layer) but equal to or smaller than a thickness obtained by adding up the minimum thickness of the ingot necessary for manufacturing the last wafer and the distributed thickness is subjected to the final flattening step.

In this case, grinding the ingot until the finishing thickness of the wafer is reached reduces the length of time necessary for manufacturing the last wafer. Hence, applying the present invention as the method for manufacturing a maximum number of wafers from each ingot while a plurality of ingots are simultaneously processed makes it unlikely for grinding of the ingots for manufacturing the last wafer from the ingots to become a bottleneck, making it possible to reduce the length of time necessary for such grinding.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view schematically illustrating an ingot;

FIG. 1B is a side view schematically illustrating the ingot depicted in FIG. 1A;

FIG. 2 is a flowchart schematically illustrating an example of a wafer manufacturing method for manufacturing three or more wafers from the ingot depicted in FIGS. 1A and 1B;

FIG. 3 is a side view schematically illustrating parameters that are referred to in a calculating step included in the wafer manufacturing method illustrated in FIG. 2;

FIG. 4 is a perspective view schematically illustrating a manner of a separation layer forming step included in the wafer manufacturing method illustrated in FIG. 2;

FIG. 5A is a cross sectional view schematically illustrating, in an enlarged form, part of the ingot that has undergone the separation layer forming step included in the wafer manufacturing method illustrated in FIG. 2;

FIG. 5B is a plan view schematically illustrating the ingot that has undergone the separation layer forming step included in the wafer manufacturing method illustrated in FIG. 2;

FIG. 6A is a side view schematically illustrating a manner of a separating step included in the wafer manufacturing method illustrated in FIG. 2;

FIG. 6B is a side view schematically illustrating the manner of the separating step included in the wafer manufacturing method illustrated in FIG. 2;

FIG. 7 is a perspective view schematically illustrating a manner of a non-final flattening step included in the wafer manufacturing method illustrated in FIG. 2;

FIG. 8 is a block diagram schematically illustrating an example of a processing apparatus for manufacturing three or more wafers from the ingot depicted in FIGS. 1A and 1B; and

FIG. 9 is a block diagram schematically illustrating another example of a processing apparatus for manufacturing three or more wafers from the ingot depicted in FIGS. 1A and 1B.

### DETAILED DESCRIPTION OF THE PREFERRED EMBODIMENT

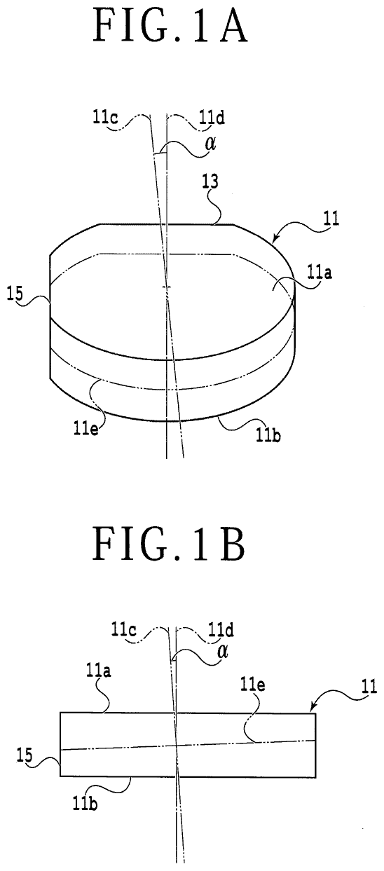

An embodiment of the present invention will be described with reference to the attached drawings. FIG. 1A is a perspective view schematically illustrating an example of an ingot, while FIG. 1B is a side view schematically illustrating the ingot depicted in FIG. 1A. The ingot denoted by 11 and depicted in FIGS. 1A and 1B is, for example, a single crystal of SiC and has a cylindrical shape having a face side 11a and a reverse side 11b that are substantially parallel to each other.

The ingot 11 is manufactured with use of epitaxial growth. Note that, in order to have fewer lattice defects inside the ingot 11, the ingot 11 is manufactured in such a manner that a c-axis 11c of SiC is slightly tilted with respect to a perpendicular line 11d of the face side 11a and the reverse side 11b. For example, an angle (off angle) a formed between the c-axis 11c and the perpendicular line 11d is 1° to 6° (typically 4°).

Further, on a side surface of the ingot 11, two flat portions, i.e., a first orientation flat 13 and a second orientation flat 15, for indicating a crystal orientation of SiC are formed. The first orientation flat 13 is longer than the second orientation flat 15. The second orientation flat 15 is formed in such a manner as to be parallel to a crossline where a plane parallel to a c-plane 11e of SiC intersects with the face side 11a or the reverse side 11b.

Note that the ingot 11 may be formed with use of, as a material, a single crystal of a substance other than SiC (for example, Si, GaN, LT, LN, or the like). Further, on the side surface of the ingot 11, one of or both the first orientation flat 13 and the second orientation flat 15 may not be provided. Moreover, in place of such orientation flats, a cutout (notch) for indicating the crystal orientation of the material constituting the ingot 11 may be formed.

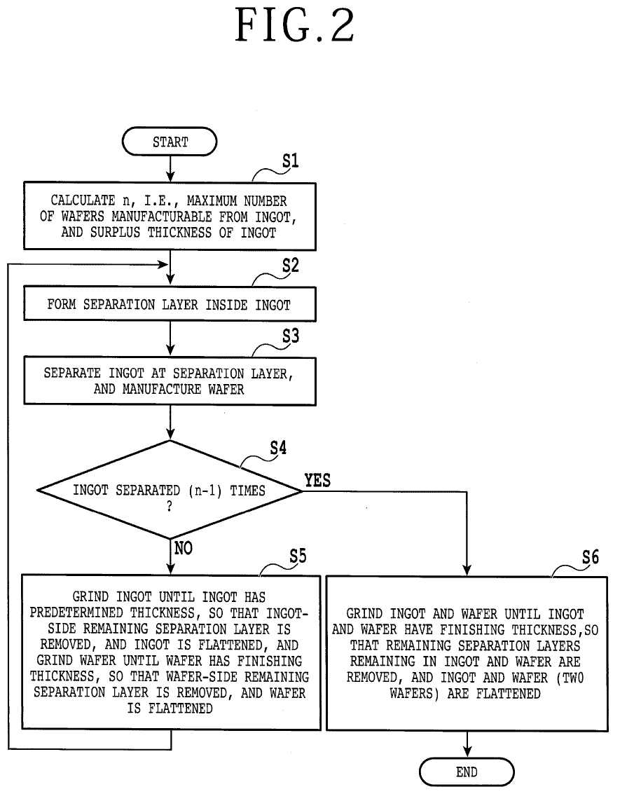

FIG. 2 is a flowchart schematically illustrating an example of the wafer manufacturing method for manufacturing three or more wafers from the ingot 11. Stated briefly, this method repeats a series of steps for separating and flattening the ingot (n−1) times which is a number obtained by subtracting one from n (n is a natural number of three or more) which is the maximum number of wafers that can be manufactured from the ingot 11 and thereby manufactures n wafers from the ingot 11.

Further, in this method, instead of being performed all at once in the series of steps performed for manufacturing the last wafer, removal of the surplus thickness (that is, a thickness that is a surplus of the thickness necessary for manufacturing n wafers) from the ingot 11 is performed in stages in each series of steps performed (n−1) times.

Specifically, in each series of steps in the method, the thickness of the ingot 11 is reduced by a thickness obtained by adding up the minimum thickness (specifically, a thickness obtained by adding up a finishing thickness of the wafer and an assumed thickness of the separation layer that are described later) of the ingot 11 that decreases in association with the manufacturing of the wafer and a distributed thickness (specifically, a thickness obtained by dividing the surplus thickness by (n−1)).

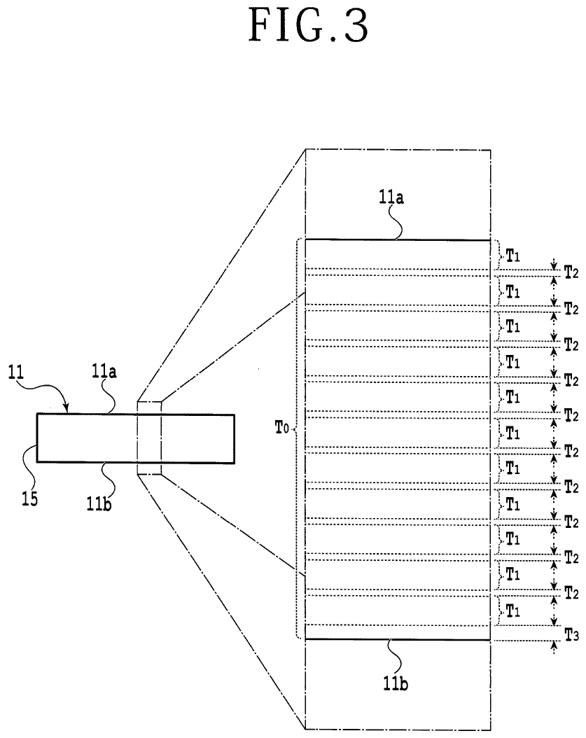

In the wafer manufacturing method illustrated in FIG. 2, first, the parameters identified beforehand are referred to, and then, n, which is the maximum number of wafers that can be manufactured from the ingot 11, and the surplus thickness of the ingot 11 are calculated (calculating step S1). FIG. 3 is a side view schematically illustrating the parameters to be referred to in the calculating step S1.

In the calculating step S1, reference is made to an initial thickness T₀ of the ingot 11, a finishing thickness (that is, a thickness of the wafer that has been flattened in a non-final flattening step S5 and a final flattening step S6 that are described later) T₁ of the wafer, and an assumed thickness (that is, a thickness which the separation layer formed inside the ingot 11 in the separation layer forming step S2 described later is assumed to have) T₂ of the separation layer.

Specifically, in this method, the ingot 11 is separated (n−1) times which is a number obtained by subtracting one from n which is the maximum number of wafers that can be manufactured from the ingot 11. Hence, the initial thickness T₀ of the ingot 11 has a value that satisfies the following inequations (1) and (2).

$$\\ \begin{matrix}[ Math . 1 ] & \\ {T}_{0} > n \times {T}_{1} + ( n - 1 ) \times {T}_{2} & ( 1 )\end{matrix}$$

$$\\ \begin{matrix}[ Math . 2 ] & \\ {T}_{0} < ( n + 1 ) \times {T}_{1} + n \times {T}_{2} & ( 2 )\end{matrix}$$

Further, when the inequations (1) and (2) above are modified, n which is the maximum number of wafers that can be manufactured from the ingot 11 can be recognized to be a natural number that satisfies the following inequation (3).

$$\\ \begin{matrix}[ Math . 3 ] & \\ ( {T}_{0} - {T}_{1} ) / ( {T}_{1} + {T}_{2} ) < n < ( {T}_{0} + {T}_{2} ) / ( {T}_{1} + {T}_{2} ) & ( 3 )\end{matrix}$$

Further, if n, which is the maximum number of wafers that can be manufactured from the ingot 11, can be calculated, the surplus thickness T₃ of the ingot 11 that is represented by the following equation (4) can also be calculated.

$$\\ \begin{matrix}[ Math . 4 ] & \\ {T}_{3} = {T}_{0} - \{ n \times {T}_{1} + ( n - 1 ) \times {T}_{2} \} & ( 4 )\end{matrix}$$

Moreover, if n, which is the maximum number of wafers that can be manufactured from the ingot 11, and the surplus thickness T₃ of the ingot 11 are calculated, a distributed thickness ΔT of the ingot 11 that is represented by the following equation (5) can also be calculated.

$$\\ \begin{matrix}[ Math . 5 ] & \\ Δ T = {T}_{3} / ( n - 1 ) & ( 5 )\end{matrix}$$

For example, when the initial thickness T₀ of the ingot 11 is 20 mm (20,000 μm), the finishing thickness T₁ of the wafer is 350 μm, and the assumed thickness T₂ of the separation layer is 80 μm, n which is the maximum number of wafers that can be manufactured from the ingot 11 is 46, and the surplus thickness T₃ of the ingot 11 is 300 μm. Further, in this case, the distributed thickness ΔT of the ingot 11 is 6.67 μm.

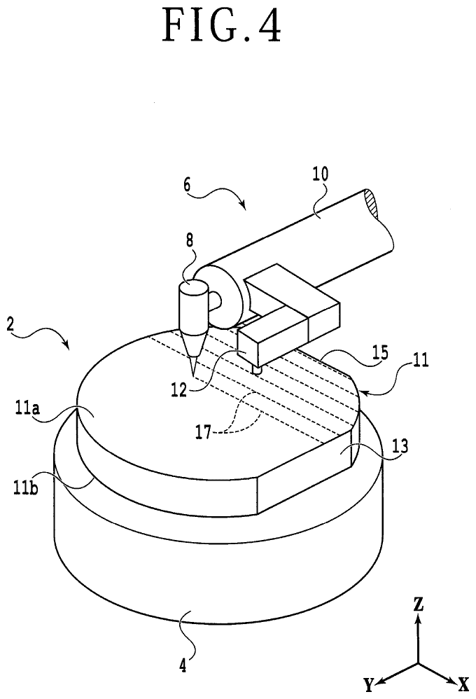

After the calculating step S1, a separation layer is formed inside the ingot 11 (separation layer forming step S2). FIG. 4 is a perspective view schematically illustrating the manner of the separation layer forming step S2. Note that an X-axis direction and a Y-axis direction that are illustrated in FIG. 4 are directions perpendicular to each other in a horizontal plane, and a Z-axis direction is a direction (vertical direction) perpendicular to the X-axis direction and the Y-axis direction.

The separation layer forming step S2 is performed in a laser processing apparatus 2. The laser processing apparatus 2 has a chuck table 4 including a circular holding surface that is substantially parallel to a horizontal plane and that can hold the ingot 11 thereon.

The chuck table 4 is coupled to a suction mechanism (not illustrated). This suction mechanism has, for example, an ejector or the like. When the suction mechanism is operated, suction force acts in a space near the holding surface of the chuck table 4. Hence, when the suction mechanism is operated in a state in which the ingot 11 is placed on the holding surface, the ingot 11 is held on the holding surface of the chuck table 4.

Further, the chuck table 4 is coupled to a rotation mechanism (not illustrated). This rotation mechanism has, for example, a pulley, a motor, and the like. When the rotation mechanism is operated, the chuck table 4 rotates about a straight line passing through the center of the holding surface and extending along the Z-axis direction, as a rotational axis.

Above the chuck table 4, a head 8 of a laser beam application unit 6 is provided. The head 8 is provided on a distal end portion of a cylindrical housing 10 extending along the Y-axis direction. Note that, the head 8 houses an optical system such as a condensing lens and a mirror, while the housing 10 houses an optical system such as a mirror and/or a lens.

A proximal end portion of the housing 10 is coupled to a moving mechanism. This moving mechanism has, for example, a ball screw, a motor, and the like. When the moving mechanism is operated, the head 8 and the housing 10 move along the X-axis direction, the Y-axis direction, and/or the Z-axis direction.

The laser beam application unit 6 includes a laser oscillator (not illustrated) that generates a laser beam having a wavelength (for example, 1,064 nm) that is transmittable through the material of the ingot 11. This laser oscillator includes, for example, a laser medium such as neodymium-doped yttrium aluminum garnet (Nd:YAG). When a laser beam is generated by the laser oscillator, the laser beam is emitted toward the holding surface side of the chuck table 4 through the optical systems housed in the housing 10 and the head 8.

Further, provided on a side portion of the housing 10 is an imaging unit 12 that is capable of capturing an image of the holding surface side of the chuck table 4. The imaging unit 12 includes, for example, a light source such as a light emitting diode (LED), an objective lens, and an imaging element such as a charge coupled device (CCD) image sensor or a complementary metal oxide semiconductor (CMOS) image sensor.

When the separation layer forming step S2 is to be performed in the laser processing apparatus 2, first, the ingot 11 is placed on the holding surface of the chuck table 4 such that the face side 11a faces upward. Next, the suction mechanism is operated such that the ingot 11 is held on the chuck table 4. Subsequently, in reference to the image of the face side 11a of the ingot 11 which has been captured by the imaging unit 12 and the like, the rotation mechanism rotates the chuck table 4 such that the second orientation flat 15 becomes parallel to the X-axis direction.

Then, the moving mechanism moves the head 8 and the housing 10 along the X-axis direction and/or the Y-axis direction such that a region in the ingot 11 that is slightly on the inner side from the second orientation flat 15 is positioned in the X-axis direction as viewed from the head 8 in plan view. Next, the moving mechanism moves the head 8 and the housing 10 along the Z-axis direction such that a focal point where the laser beam emitted from the head 8 is focused is positioned to a predetermined depth from the face side 11a of the ingot 11.

The predetermined depth is set with reference to the parameters identified beforehand. Specifically, the predetermined depth is set to be equal to or greater than a thickness (first thickness) obtained by adding up the finishing thickness T₁ of the wafer and a thickness of the separation layer (wafer-side remaining separation layer) that remains in the wafer after the wafer has been separated from the ingot 11 but equal to or smaller than a thickness (second thickness) that is obtained by adding up the first thickness and the distributed thickness ΔT of the ingot 11. Further, in brief, the thickness of the wafer-side remaining separation layer is a thickness corresponding to a thickness obtained by subtracting the thickness of the separation layer (ingot-side remaining separation layer) that remains in the ingot 11 after the wafer has been separated from the ingot 11 from the assumed thickness T₂ of the separation layer.

Next, while a laser beam is emitted from the head 8, the moving mechanism moves the head 8 and the housing 10 along the X-axis direction such that the focal point where the laser beam is focused passes through the ingot 11 from one end to the other end thereof in the X-axis direction. That is, while a laser beam is applied to the ingot 11, the ingot 11 and the focal point where the laser beam is focused are moved relative to each other along a crossline where a plane parallel to the c-plane 11e of the material (here, SiC) of the ingot 11 intersects with the face side 11a.

Subsequently, the moving mechanism moves the head 8 and the housing 10 along the Y-axis direction such that the head 8 is positioned in the X-axis direction as viewed from a region slightly farther from the second orientation flat 15 than the region to which the laser beam has already been applied, in plan view. Then, a laser beam is applied again to the ingot 11 as described above.

Further, until the completion of laser beam application to the region in the ingot 11 that is farthest from the second orientation flat 15, the movement of the head 8 and the housing 10 along the Y-axis direction and the application of the laser beam to the ingot 11 are repeated. This completes the separation layer forming step S2.

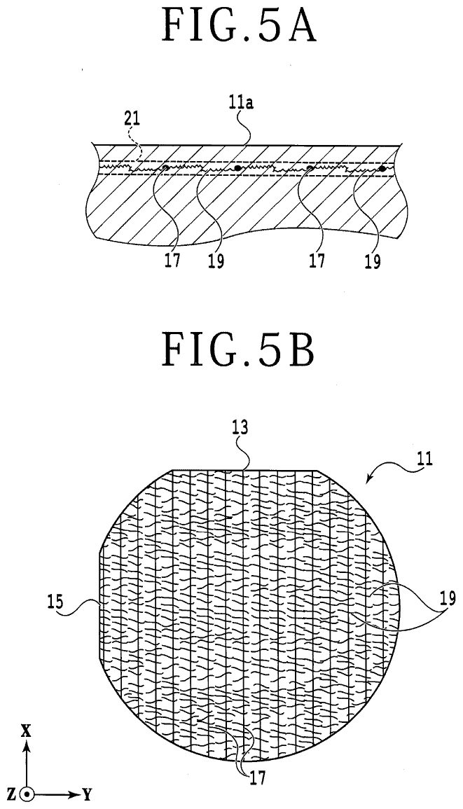

FIG. 5A is a cross sectional view schematically illustrating, in an enlarged form, part of the ingot 11 that has undergone the separation layer forming step S2, while FIG. 5B is a plan view schematically illustrating the ingot 11 that has undergone the separation layer forming step S2. In the separation layer forming step S2, the modified portions 17 in which the crystal structure of the material (here, SiC) of the ingot 11 is disordered are formed inside the ingot 11 with the focal point where the laser beam is focused as the center.

Further, when the modified portions 17 are formed inside the ingot 11, the volume of the ingot 11 expands, and internal stress is generated in the ingot 11. This internal stress is mitigated by cracks 19 extending from the modified portions 17. Note that the cracks 19 mainly extend along the c-plane 11e. As a result, a separation layer 21 that includes a plurality of modified portions 17 and the cracks 19 extending from the plurality of modified portions 17 is formed inside the ingot 11.

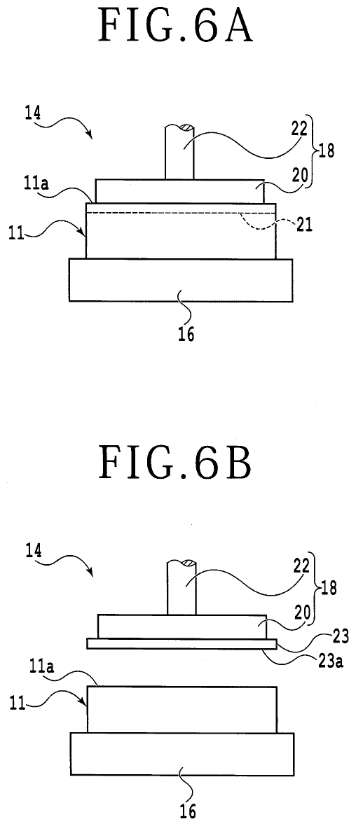

After the separation layer forming step S2, a wafer is manufactured by the ingot 11 being separated at the separation layer 21 (separating step 3). FIGS. 6A and 6B are each a side view schematically illustrating the manner of the separating step S3. The separating step S3 is performed in a separating apparatus 14. The separating apparatus 14 includes a chuck table 16 having the same structure as the chuck table 4 illustrated in FIG. 4.

The chuck table 16 is coupled to a table-side suction mechanism (not illustrated). The table-side suction mechanism has, for example, a vacuum pump or the like. When this table-side suction mechanism is operated, suction force acts in a space near a holding surface of the chuck table 16. Hence, when the table-side suction mechanism is operated in a state in which the ingot 11 is placed on the holding surface, the ingot 11 is held on the holding surface of the chuck table 16.

Above the chuck table 16, there is provided a separating unit 18. The separating unit 18 has a suction plate 20 which has, on its lower surface, a plurality of suction ports. The plurality of suction ports are in communication with a separating unit-side suction mechanism such as a vacuum pump via suction channels formed inside the suction plate 20. When the separating unit-side suction mechanism is operated, suction force acts in a space near the lower surface of the suction plate 20.

Further, an upper portion of the suction plate 20 is coupled to a vertical direction moving mechanism 22. The vertical direction moving mechanism 22 has, for example, an air cylinder or the like. When the vertical direction moving mechanism 22 is operated, the suction plate 20 moves along the vertical direction.

When the separating step S3 is to be performed in the separating apparatus 14, first, the ingot 11 in which the separation layer 21 is formed in the inside thereof is placed on the holding surface of the chuck table 16 such that the face side 11a faces upward, in a state in which the chuck table 16 and the suction plate 20 are sufficiently spaced from each other. Next, the table-side suction mechanism is operated such that the ingot 11 is held on the chuck table 16.

Subsequently, the vertical direction moving mechanism 22 lowers the suction plate 20 such that the lower surface of the suction plate 20 comes into contact with the face side 11a of the ingot 11 (see FIG. 6A). Then, the separating unit-side moving mechanism is operated such that the face side 11a of the ingot 11 is sucked toward the upper side.

Next, the vertical direction moving mechanism 22 lifts the suction plate 20 such that the suction plate 20 is spaced from the chuck table 16 (see FIG. 6B). At this time, tensile stress acts on the ingot 11, and the cracks 19 included in the separation layer 21 further extend.

As a result, the ingot 11 is separated at the separation layer 21, and an ingot 11 in which the face side 11a includes the ingot-side remaining separation layer and a wafer 23 in which one side includes the wafer-side remaining separation layer are manufactured. Note that each of the face side 11a of the ingot 11 and the one side of the wafer 23 has a recessed and protruding shape reflecting the distribution of the modified portions 17 and the cracks 19 in the separation layer 21. This completes the separating step S3.

When the ingot 11 has not yet been separated (n−1) times (step S4: NO), the ingot 11 is ground until the ingot 11 has a predetermined thickness, so that the ingot-side remaining separation layer is removed, and the ingot 11 is flattened, and the wafer 23 is ground until the wafer 23 has the finishing thickness T₁, so that the wafer-side remaining separation layer is removed, and the wafer 23 is flattened (non-final flattening step S5).

Note that the predetermined thickness is a thickness that is smaller than the thickness of the ingot 11 as of the point in time of start of the series of steps including the separation layer forming step S2, the separating step S3, and the non-final flattening step S5 (that is, the point in time of start of the separation layer forming step S2), by a thickness obtained by adding up the finishing thickness T₁ of the wafer 23, the assumed thickness T₂ of the separation layer 21, and the distributed thickness ΔT of the ingot 11.

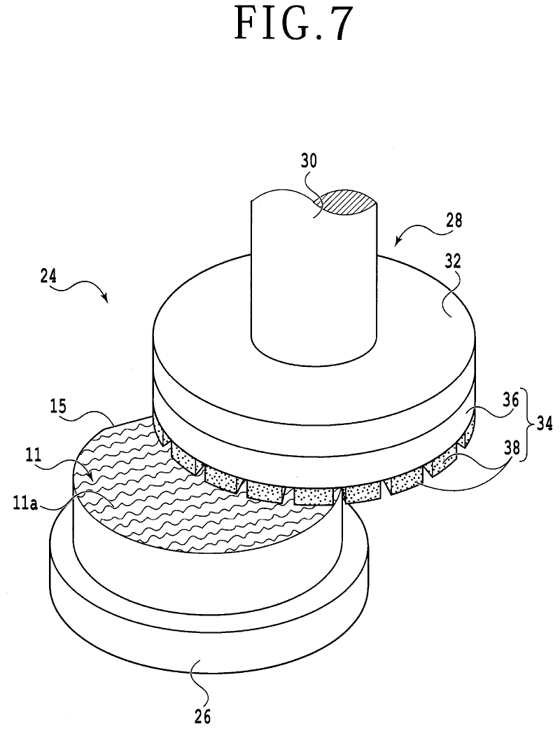

FIG. 7 is a perspective view schematically illustrating the manner of the non-final flattening step S5. The non-final flattening step S5 is performed in a grinding apparatus 24. The grinding apparatus 24 includes a chuck table 26 having a holding surface that has a shape corresponding to a conical side surface in which the center is slightly protruding than the outer edge and that can hold the wafer 23 thereon.

The chuck table 26 is coupled to a suction mechanism. This suction mechanism has an ejector or the like. When the suction mechanism is operated, suction force acts in a space near the holding surface of the chuck table 26. Hence, when the suction mechanism is operated in a state in which the ingot 11 or the wafer 23 is placed on the holding surface, the ingot 11 or the wafer 23 is held on the holding surface of the chuck table 26.

Further, the chuck table 26 is coupled to a horizontal direction moving mechanism. The horizontal direction moving mechanism has, for example, a ball screw, a motor, and the like. When the horizontal direction moving mechanism is operated, the chuck table 26 moves along the horizontal direction.

Further, the chuck table 26 is coupled to a rotation mechanism (not illustrated). The rotation mechanism has, for example, a pulley, a motor, and the like. When the rotation mechanism is operated, the chuck table 26 rotates about a straight line passing through the center of the holding surface, as the rotational axis.

Provided near the chuck table 26 is a measuring unit (not illustrated). The measuring unit has, for example, a contact-type or non-contact-type thickness measuring instrument or the like. The measuring unit can measure the thickness of the ingot 11 or the wafer 23 that is held on the holding surface of the chuck table 26.

Above the chuck table 26, a grinding unit 28 is provided. The grinding unit 28 has a spindle 30 whose upper end portion is coupled to a motor. A lower end portion of the spindle 30 is provided with a disk-shaped mount 32, and a grinding wheel 34 is mounted on the mount 32.

The grinding wheel 34 includes an annular base 36 and a plurality of grindstones 38 disposed in a spaced manner along a circumferential direction of the base 36. Lower surfaces of the plurality of grindstones 38 are disposed at substantially the same height, and serve as the grinding surfaces for grinding the ingot 11 and the wafer 23.

The spindle 30 is coupled to a vertical direction moving mechanism. The vertical direction moving mechanism has, for example, a ball screw, a motor, and the like. When the vertical direction moving mechanism is operated, the spindle 30, the mount 32, and the grinding wheel 34 move along the vertical direction.

When the non-final flattening step S5 is to be performed in the grinding apparatus 24, for example, the wafer 23 is ground to the finishing thickness T₁ after the ingot 11 has been ground to the predetermined thickness described above. In this case, first, in a state in which the chuck table 26 and the grinding wheel 34 are sufficiently spaced from each other in each of the horizontal direction and the vertical direction, the ingot 11 is placed on the holding surface of the chuck table 26 in such a manner that the face side 11a faces upward.

Next, the suction mechanism is operated such that the ingot 11 is held on the chuck table 26. Subsequently, the horizontal direction moving mechanism moves the chuck table 26 such that the center of the holding surface of the chuck table 26 and the trajectory followed by the plurality of grindstones 38 when the grinding wheel 34 is rotated together with the spindle 30 overlap in the vertical direction.

Then, the rotation mechanism is operated to rotate the chuck table 26, and the motor coupled to the upper end portion of the spindle 30 is operated to rotate the grinding wheel 34. Next, the spindle 30, the mount 32, and the grinding wheel 34 are lowered by the vertical direction moving mechanism such that the grinding surface of any of the plurality of grindstones 38 comes into contact with the face side 11a of the ingot 11.

This starts grinding of the ingot 11. This grinding, i.e., lowering the grinding wheel 34 while both the chuck table 26 and the grinding wheel 34 are rotated, is continued until the thickness of the ingot 11 measured by the measuring unit reaches the abovementioned predetermined thickness.

When the grinding of the ingot 11 is completed, the horizontal direction moving mechanism and the vertical direction moving mechanism are operated such that rotation of both the chuck table 26 and the grinding wheel 34 is stopped and the chuck table 26 and the grinding wheel 34 are sufficiently spaced from each other in each of the horizontal direction and the vertical direction.

Next, the wafer 23 is ground to the finishing thickness T₁ by a procedure similar to the one described above. This completes the non-final flattening step S5. Note that, in the non-final flattening step S5, one of the grinding of the ingot 11 or the grinding of the wafer 23 may be performed in a grinding apparatus different from the grinding apparatus 24. In this case, grinding of the ingot 11 can be performed in tandem with grinding of the wafer 23.

Further, the thickness of the ingot 11 and the thickness of the wafer 23 each of which is to be removed in the non-final flattening step S5 change depending on the abovementioned predetermined depth (that is, the distance between the focal point of the laser beam to be applied to the ingot 11 in the separation layer forming step S2 and the face side 11a of the ingot 11).

Specifically, in a case where the predetermined depth corresponds to the abovementioned first thickness (that is, the thickness obtained by adding up the finishing thickness T₁ of the wafer 23 and the thickness of the wafer-side remaining separation layer), the thickness of the ingot 11 to be removed in the non-final flattening step S5 corresponds to a thickness obtained by adding up the thickness of the ingot-side remaining separation layer and the distributed thickness ΔT of the ingot 11, while the thickness of the wafer 23 to be removed in the non-final flattening step S5 corresponds to the thickness of the wafer-side remaining separation layer.

In this case, even if the cracks 19 inadvertently extend longer toward the reverse side 11b of the ingot 11 in the separation layer forming step S2 and the separating step S3, it is highly likely that the ingot 11 can be flattened without the cracks 19 remaining in the ingot 11.

Further, in a case where the predetermined depth corresponds to the second thickness mentioned above (that is, the thickness obtained by adding up the first thickness and the distributed thickness ΔT of the ingot 11), the thickness of the ingot 11 to be removed in the non-final flattening step S5 corresponds to the thickness of the ingot-side remaining separation layer, while the thickness of the wafer 23 to be removed in the non-final flattening step S5 corresponds to the thickness obtained by adding up the thickness of the wafer-side remaining separation layer and the distributed thickness ΔT of the ingot 11.

In this case, even if the cracks 19 inadvertently extend longer toward the face side 11a of the ingot 11 in the separation layer forming step S2 and the separating step S3, it is highly likely that the wafer 23 can be flattened without the cracks 19 remaining in the wafer 23.

Further, in a case where the predetermined depth is greater than the first thickness but smaller than the second thickness, the thickness of the ingot 11 to be removed in the non-final flattening step S5 corresponds to a thickness obtained by adding up the thickness of the ingot-side remaining separation layer and a thickness obtained by multiplying the distributed thickness ΔT of the ingot 11 by (k/k+1) (k is a positive real number), while the thickness of the wafer 23 to be removed in the non-final flattening step S5 corresponds to a thickness obtained by adding up the thickness of the wafer-side remaining separation layer and a thickness obtained by multiplying the distributed thickness ΔT of the ingot 11 by (1/k+1).

In this case, even if the cracks 19 inadvertently extend to some extent toward the face side 11a and the reverse side 11b of the ingot 11 in the separation layer forming step S2 and the separating step S3, it is highly likely that both the ingot 11 and the wafer 23 can be flattened without the cracks 19 remaining in both the ingot 11 and the wafer 23.

After the non-final flattening step S5, the separation layer forming step S2 and the separating step S3 are performed again. Further, until the ingot 11 is separated (n−1) times, the non-final flattening step S5, the separation layer forming step S2, and the separating step S3 are repeated in turn.

When the ingot 11 is separated (n−1) times (step S4: YES), each of the ingot 11 and the wafer 23 is ground to the finishing thickness T₁, so that the separation layers remaining in the ingot 11 and the wafer 23 (that is, the ingot-side remaining separation layer and the wafer-side remaining separation layer) are removed, and the ingot 11 and the wafer 23 (two wafers) are flattened (final flattening step S6).

Note that the thickness of the ingot 11 as of the point in time when the series of steps including the separation layer forming step S2, the separating step S3, and the final flattening step S6 is to be started (that is, the point in time when the separation layer forming step S2 that is to be performed for the last time is to be started) corresponds to a thickness obtained by adding up a thickness obtained by doubling the finishing thickness T₁ of the wafer 23, the assumed thickness T₂ of the separation layer 21, and the distributed thickness ΔT of the ingot 11.

Further, the thickness of the ingot 11 as of the point in time when the final flattening step S6 is to be started is equal to or greater than the minimum thickness of the ingot 11 necessary for manufacturing the last wafer 23 (specifically, a thickness obtained by adding up the finishing thickness T₁ of the wafer 23 and the thickness of the ingot-side remaining separation layer) but equal to or smaller than a thickness obtained by adding up the minimum thickness of the ingot 11 necessary for manufacturing the last wafer 23 and the distributed thickness ΔT of the ingot 11.

The final flattening step S6 is performed in a manner similar to that of the non-final flattening step S5 described above. Hence, detailed description of the final flattening step S6 is omitted here. Upon completion of the final flattening step S6, manufacturing n wafers 23 from the ingot 11 is completed. In other words, the wafer manufacturing method illustrated in FIG. 2 is completed.

In the non-final flattening step S5 included in the series of steps for manufacturing the wafers 23 from the ingot 11 in the wafer manufacturing method illustrated in FIG. 2, the ingot 11 is ground until the ingot 11 has a thickness that is smaller than the thickness of the ingot 11 as of the point in time when the series of steps is to be started, by the thickness obtained by adding up the finishing thickness T₁ of the wafer 23, the assumed thickness T₂ of the separation layer 21, and the distributed thickness ΔT of the ingot 11 obtained by dividing the surplus thickness T₃ of the ingot 11 by (n−1) which is a number obtained by subtracting one from n which is the maximum number of wafers 23 that can be manufactured from the ingot 11.

When the series of steps is repeated, an ingot 11 having a thickness that is equal to or greater than the minimum thickness of the ingot 11 necessary for manufacturing the last wafer 23 (specifically, the thickness obtained by adding up the finishing thickness T₁ of the wafer 23 and the thickness of the ingot-side remaining separation layer) but is equal to or smaller than the thickness obtained by adding up the minimum thickness of the ingot 11 necessary for manufacturing the last wafer 23 and the distributed thickness ΔT of the ingot 11 is subjected to the final flattening step S6.

In this case, grinding the ingot 11 until the finishing thickness T₁ of the wafer 23 is obtained reduces the length of time necessary for manufacturing the last wafer 23. Hence, applying the wafer manufacturing method illustrated in FIG. 2 as the method for manufacturing the maximum n wafers 23 from each ingot 11 while simultaneously processing a plurality of ingots 11 makes it unlikely for the grinding of the ingot 11 for manufacturing the last wafer 23 from each ingot 11 to become a bottleneck, making it possible to reduce the length of time necessary for manufacturing the last wafer 23.

Note that the details described above are one mode of the present invention, the present invention is not limited to the details described above. For example, in the present invention, before the calculating step S1, a measuring step of measuring the initial thickness T₀ of the ingot 11 may be performed.

Further, in the present invention, after the separation layer forming step S2 but before the separating step S3, an ultrasonic wave applying step of applying ultrasonic waves to the face side 11a of the ingot 11 may be performed. In this case, the cracks 19 included in the separation layer 21 extend in the ultrasonic wave applying step, and the ingot 11 is easily separated in the separating step S3.

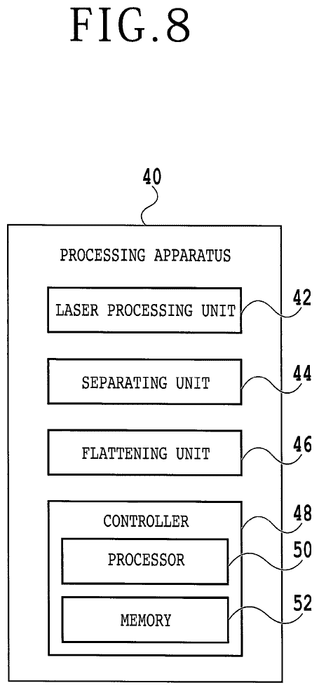

Further, the present invention may relate to a processing apparatus for manufacturing three or more wafers 23 from the ingot 11. FIG. 8 is a block diagram schematically illustrating an example of such a processing apparatus. The processing apparatus denoted by 40 and illustrated in FIG. 8 includes a laser processing unit 42, a separating unit 44, a flattening unit 46, and a controller 48.

The laser processing unit 42 has, for example, a structure similar to that of the laser processing apparatus 2 illustrated in FIG. 4. Hence, in the laser processing unit 42, the separation layer 21 can be formed inside the ingot 11 in the manner described above.

The separating unit 44 has, for example, a structure similar to that of the separating apparatus 14 illustrated in FIGS. 6A and 6B. Hence, in the separating unit 44, the ingot 11 can be separated at the separation layer 21, and the wafer 23 can be manufactured, in the manner described above.

The flattening unit 46 has, for example, a structure similar to that of the grinding apparatus 24 illustrated in FIG. 7. Hence, in the flattening unit 46, the ingot-side remaining separation layer remaining in the ingot 11 and the wafer-side remaining separation layer remaining in the wafer 23 can each be removed, and each of the ingot 11 and the wafer 23 can be flattened, in the manner described above.

Note that, in the flattening unit 46, only the flattening of the ingot 11 may be performed. In this case, a flattening unit different from the flattening unit 46 may be provided in the processing apparatus 40, and perform flattening of the wafer 23. Alternatively, in this case, flattening of the wafer 23 may be performed in an apparatus (for example, a grinding apparatus) different from the processing apparatus 40.

The controller 48 includes a processor 50 and a memory 52. The processor 50 includes, for example, a central processing unit (CPU) and the like. Further, the memory 52 includes, for example, a volatile memory such as a dynamic random access memory (DRAM) or a static random access memory (SRAM) and a non-volatile memory such as a solid state drive (SSD) (a Not AND (NAND) flash memory) or a hard disk drive (HDD) (a magnetic storage device).

The memory 52 stores data, programs, and the like used in the processor 50. Examples of the data include, for example, the initial thickness T₀ of the ingot 11, the finishing thickness T₁ of the wafer 23, the assumed thickness T₂ of the separation layer 21, the thickness of the ingot-side remaining separation layer, and the thickness of the wafer-side remaining separation layer. Further, examples of the programs include programs used for performing the wafer manufacturing method illustrated in FIG. 2 in the processing apparatus 40.

The processor 50 reads out and executes the programs stored in the memory 52 while using the data stored in the memory 52. For example, the processor 50 refers to the initial thickness T₀ of the ingot 11 and other relevant data items stored in the memory 52 and reads out from the memory 52 the program for performing the wafer manufacturing method illustrated in FIG. 2, to execute the program.

Specifically, when the wafer manufacturing method illustrated in FIG. 2 is to be performed in the processing apparatus 40, first, the processor 50 refers to the initial thickness T₀ of the ingot 11, the finishing thickness T₁ of the wafer 23, and the assumed thickness T₂ of the separation layer 21 that are stored in the memory 52, and calculates n, which is the maximum number of wafers 23 that can be manufactured from the ingot 11, and the surplus thickness T₃ of the ingot 11 (calculating step S1).

Further, the processor 50 causes the memory 52 to store n, i.e., the maximum number of wafers 23 that can be manufactured from the ingot 11, and the surplus thickness T₃ of the ingot 11. Further, the processor 50 may calculate the distributed thickness ΔT of the ingot 11 by referring to n, i.e., the maximum number of wafers 23 that can be manufactured from the ingot 11, and the surplus thickness T₃ of the ingot 11, and may cause the memory 52 to store the calculated distributed thickness ΔT.

When the calculating step S1 is completed, the processor 50 controls the laser processing unit 42, the separating unit 44, and the flattening unit 46 such that the series of steps including the forming of the separation layer 21 (the separation layer forming step S2), the separating of the ingot 11 (the separating step S3), and the flattening of the ingot 11 (the non-final flattening step S5 or the final flattening step S6) is repeated (n−1) times, which is a number obtained by subtracting one from n, i.e., the maximum number of wafers 23 that can be manufactured from the ingot 11.

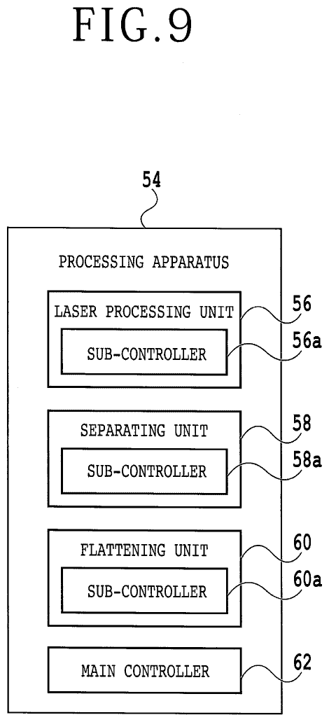

Further, in the processing apparatus according to the present invention, instead of all the processing units (specifically, the laser processing unit, the separating unit, and the flattening unit) being controlled by one controller, each processing unit may be provided with one controller and controlled by a different controller. FIG. 9 is a block diagram schematically illustrating an example of a processing apparatus in which a controller is provided for each processing unit.

The processing apparatus denoted by 54 and illustrated in FIG. 9 includes a laser processing unit 56 having a sub-controller 56a, a separating unit 58 having a sub-controller 58a, a flattening unit 60 having a sub-controller 60a, and a main controller 62. In other words, the processing apparatus 54 has a structure similar to that of the processing apparatus 40 illustrated in FIG. 8, except that the controller 48 is divided into the sub-controllers 56a, 58a, and 60a and the main controller 62.

The laser processing unit 56 has, for example, the sub-controller 56a including a processor and a memory, in addition to the constituent elements similar to those of the laser processing apparatus 2 illustrated in FIG. 4. This memory stores, for example, data, programs, and the like necessary for performing the forming of the separation layer 21 (the separation layer forming step S2) in the laser processing unit 56.

The separating unit 58 has, for example, the sub-controller 58a including a processor and a memory, in addition to the constituent elements similar to those of the separating apparatus 14 illustrated in FIGS. 6A and 6B. This memory stores, for example, data, programs, and the like necessary for performing the separating of the ingot 11 (the separating step S3) in the separating unit 58.

The flattening unit 60 has, for example, the sub-controller 60a including a processor and a memory, in addition to the constituent elements similar to those of the grinding apparatus 24 illustrated in FIG. 7. This memory stores, for example, data, programs, and the like necessary for performing the flattening of the ingot 11 and the wafer 23 (the non-final flattening step S5 and the final flattening step S6) in the flattening unit 60.

Note that, in the flattening unit 60, only the flattening of the ingot 11 may be performed. In this case, a flattening unit different from the flattening unit 60 may be provided in the processing apparatus 54, and perform flattening of the wafer 23. Alternatively, in this case, flattening of the wafer 23 may be performed in an apparatus (for example, a grinding apparatus) different from the processing apparatus 54.

The main controller 62 includes a processor and a memory. This memory stores in advance, for example, the initial thickness T₀ of the ingot 11, the finishing thickness T₁ of the wafer 23, the assumed thickness T₂ of the separation layer 21, the thickness of the ingot-side remaining separation layer, and the thickness of the wafer-side remaining separation layer. Further, the main controller 62 is connected to the sub-controllers 56a, 58a, and 60a via a wired or wireless communication line.

In the processing apparatus 54, the calculating step S1 is carried out by the main controller 62. Specifically, the processor of the main controller 62 calculates n, i.e., the maximum number of wafers 23 that can be manufactured from the ingot 11, and the surplus thickness T₃ of the ingot 11, by referring to the initial thickness T₀ of the ingot 11, the finishing thickness T₁ of the wafer 23, and the assumed thickness T₂ of the separation layer 21 that are stored in the memory of the main controller 62.

Further, the processor of the main controller 62 transmits, to the sub-controller 56a, data necessary for identifying the predetermined depth described above (that is, the distance between the focal point of the laser beam to be applied to the ingot 11 in the separation layer forming step S2 and the face side 11a of the ingot 11). Note that this data includes, for example, the finishing thickness T₁ of the wafer 23, the thickness of the wafer-side remaining separation layer, and data (specifically, n, i.e., the maximum number of wafers 23 that can be manufactured from the ingot 11, and the surplus thickness T₃ of the ingot 11) necessary for calculating the distributed thickness ΔT of the ingot 11.

Further, the processor of the main controller 62 transmits, to the sub-controller 60a, data necessary for identifying the predetermined thickness described above. Note that the data includes, for example, the finishing thickness T₁ of the wafer 23, the assumed thickness T₂ of the separation layer 21, and the data necessary for calculating the distributed thickness ΔT of the ingot 11.

Note that the processor of the main controller 62 may calculate the distributed thickness ΔT of the ingot 11 in addition to n, i.e., the maximum number of wafers that can be manufactured from the ingot 11, and the surplus thickness T₃ of the ingot 11. In this case, the processor of the main controller 62 may transmit, to the sub-controllers 56a and 60a, the distributed thickness ΔT of the ingot 11 per se, in place of the data necessary for calculating the distributed thickness ΔT of the ingot 11.

When the calculating step S1 is completed in the main controller 62, the main controller 62 transmits a signal instructing the sub-controller 56a to perform the forming of the separation layer 21 (the separation layer forming step S2) in the laser processing unit 56. Further, when the separation layer forming step S2 is completed by the sub-controller 56a controlling the constituent elements similar to those of the laser processing apparatus 2 illustrated in FIG. 4, a signal indicating the completion is transmitted from the sub-controller 56a to the main controller 62.

When the signal from the sub-controller 56a is received by the main controller 62, the main controller 62 transmits a signal instructing the sub-controller 58a to perform the separating of the ingot 11 (the separating step S3) in the separating unit 58. Further, when the separating step S3 is completed by the sub-controller 58a controlling the constituent elements similar to those of the separating apparatus 14 illustrated in FIGS. 6A and 6B, a signal indicating the completion is transmitted from the sub-controller 58a to the main controller 62.

When the signal from the sub-controller 58a is received by the main controller 62, the main controller 62 transmits a signal instructing the sub-controller 60a to perform flattening of the ingot 11 (the non-final flattening step S5) in the flattening unit 60. Further, when the non-final flattening step S5 is completed by the sub-controller 60a controlling the constituent elements similar to those of the grinding apparatus 24 illustrated in FIG. 7, a signal indicating the completion is transmitted from the sub-controller 60a to the main controller 62.

Further, transmission and reception of signals between the sub-controllers 56a, 58a, and 60a and the main controller 62 are repeated until the signal indicating the completion of the separating step S3 is received from the sub-controller 58a by the main controller 62 (n−1) times, which is a number obtained by subtracting one from n, i.e., the maximum number of wafers 23 that can be manufactured from the ingot 11.

Further, when the signal from the sub-controller 58a is received by the main controller 62 (n−1) times, the main controller 62 transmits a signal instructing the sub-controller 60a to perform flattening of the ingot 11 (the final flattening step S6) in the flattening unit 60. Further, when the final flattening step S6 is completed by the sub-controller 60a controlling the constituent elements similar to those of the grinding apparatus 24 illustrated in FIG. 7, a signal indicating the completion is transmitted from the sub-controller 60a to the main controller 62.

In addition, the processing apparatus 40 or 54 may include additional constituent elements. For example, the processing apparatus 40 or 54 may be provided with a measuring unit for measuring the initial thickness T₀ of the ingot 11. Further, the processing apparatus 40 or 54 may be provided with a conveying unit for conveying the ingot 11 into any of the laser processing unit 42 or 56, the separating unit 44 or 58, and the flattening unit 46 or 60 or conveying out the ingot 11 from any of the abovementioned units.

Furthermore, the structures, methods, and other relevant matters related to the abovementioned embodiment can be modified and implemented as appropriate without departing the scope of object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer manufacturing method for manufacturing three or more wafers from an ingot by repeating a series of steps including a separation layer forming step of forming a separation layer inside the ingot, a separating step of manufacturing each of the wafers by separating the ingot at the separation layer, after the separation layer forming step, and a flattening step of flattening each of the ingot and the wafer by removing each of an ingot-side remaining separation layer remaining in the ingot and a wafer-side remaining separation layer remaining in the wafer, after the separating step, the wafer manufacturing method comprising:
a calculating step of calculating a maximum number of the wafers manufacturable from the ingot and a surplus thickness of the ingot by referring to an initial thickness of the ingot, a finishing thickness of the wafer, and an assumed thickness of the separation layer, prior to manufacturing three or more of the wafers from the ingot, wherein,
in the separation layer forming step, the separation layer is formed by moving, relative to each other, the ingot and a focal point where a laser beam having a wavelength transmittable through a material of the ingot is focused, while the laser beam is applied to the ingot such that the focal point is positioned to a predetermined depth from a face side of the ingot, and,
in the flattening step,
the ingot is ground until the ingot has a thickness smaller than a thickness of the ingot as of the point in time when the series of steps is to be started, by a thickness obtained by adding up the finishing thickness, the assumed thickness, and a distributed thickness obtained by dividing the surplus thickness by a number obtained by subtracting one from the maximum number, and
the wafer is ground until the wafer has the finishing thickness.

2. The wafer manufacturing method according to claim 1, wherein the predetermined depth is a depth corresponding to a first thickness obtained by adding up the finishing thickness and a thickness of the wafer-side remaining separation layer.

3. The wafer manufacturing method according to claim 1, wherein the predetermined depth is a depth corresponding to a second thickness obtained by adding up the finishing thickness, a thickness of the wafer-side remaining separation layer, and the distributed thickness.

4. The wafer manufacturing method according to claim 1, wherein the predetermined depth is a depth greater than a first thickness obtained by adding up the finishing thickness and a thickness of the wafer-side remaining separation layer but smaller than a second thickness obtained by adding up the first thickness and the distributed thickness.

5. A processing apparatus for manufacturing three or more wafers from an ingot, comprising:
a laser processing unit for forming a separation layer inside the ingot;
a separating unit for manufacturing each of the wafers by separating the ingot at the separation layer;
a flattening unit for flattening the ingot by removing an ingot-side remaining separation layer remaining in the ingot; and
a controller that controls the laser processing unit, the separating unit, and the flattening unit such that a series of steps including forming of the separation layer, separating of the ingot, and flattening of the ingot is repeated the number of times obtained by subtracting one from a maximum number of the wafers manufacturable from the ingot, wherein
the controller includes
a memory for storing an initial thickness of the ingot, a finishing thickness of the wafers, and an assumed thickness of the separation layer, and
a processor for calculating the maximum number and a surplus thickness of the ingot by referring to the initial thickness, the finishing thickness, and the assumed thickness, and
the processor
controls the laser processing unit such that the separation layer is formed by moving, relative to each other, the ingot and a focal point where a laser beam having a wavelength transmittable through a material of the ingot is focused, while the laser beam is applied to the ingot in such a manner that the focal point is positioned to a predetermined depth from a face side of the ingot, and
controls the flattening unit such that the ingot is ground until the ingot has a thickness smaller than a thickness of the ingot as of the point in time when the series of steps is to be started, by a thickness obtained by adding up the finishing thickness, the assumed thickness, and a distributed thickness obtained by dividing the surplus thickness by a number obtained by subtracting one from the maximum number.
